(19) United States
(12) Patent Application Publication
(10) Pub. No.: US 2010/0157522 A1
(43) Pub. Date: Jun. 24, 2010

(54) Alternative Form Factor Computing Device with Cycling Air Flow

(76) Inventor: Gamal Refai-Ahmed, Ontario (CA)

Correspondence Address: TIMOTHY M HONEYCUTT ATTORNEY AT LAW, P O BOX 1577, CYPRESS, TX, 77410, US

(21) Appl. No.: 12/339,312

(22) Filed: Dec. 19, 2008

(51) Int. Cl. H05K 7/20; F28F 7/00; B23P 11/00

(52) U.S. Cl. 361/679.54; 165/80.3; 29/428

(57) ABSTRACT

Various apparatus and methods of removing heat from devices in a computing device. In one aspect, a method of removing heat from a semiconductor chip in an enclosure of a computing device is provided. Heat from the semiconductor chip is transferred using a heat sink that is thermally coupled to the semiconductor chip. Air is moved using an air mover positioned in the enclosure. The air mover is operable to move the air past the heat sink and recycle at least a portion of the air to again pass the heat sink.

### BACKGROUND OF THE INVENTION

1. Field of the Invention

This invention relates generally to semiconductor chip systems, and more particularly to methods and apparatus for thermally managing computing devices.

2. Description of the Related Art

A conventional game console shares many attributes with present-day personal computers, including a system board with plural integrated circuits mounted thereon, various data storage devices, such as optical disk and hard disk drives, and a power supply all housed within an enclosure of one sort or another. Many conventional game console designs include not only a central processing unit (CPU) but also a dedicated graphics processing unit (GPU). In recent years the GPU's and CPU's used in game consoles have increased dramatically in complexity. This increase in circuit complexity has produced an attendant increase in the heat generated by GPU's and CPU's.

Heat buildup within a game console and enclosure is potentially troublesome not only for the high-power dissipation devices, such as the various processors and memory devices, but also for all of the other components housed within the console enclosure, including the date data storage devices, chipsets and even the various passive components on a typical system board. To transfer heat from various internal components, many conventional game console designs incorporate a heat sink in thermal contact with the higher heat dissipating devices along with a cooling fan. One common conventional cooling enclosure combination involves the use of an axial flow fan positioned proximate air inlets positioned at one end of the console. The axial flow fan is operable to take air through the intake vent and pass the intake air unidirectionally across the console and out one or more discharge vents.

One difficulty associated with this conventional axial enclosure arrangement is that the fan's very close proximity to the intake vent results in a higher acoustic signature due to both the noise of the fan itself and also the noise of air blowing past the vents. The conventional axial flow cooling design utilizes a single pass scheme in which air is passed over the internal components of the game console one time before exiting out a discharge vent. It is often the case that the discharged air is still several or even tens of degrees cooler than the components in the console. However, since the air is blown out of the enclosure, the potential convective benefit of the air is lost. Finally, axial flow fans tend to have a relatively large vertical footprint in order to accommodate the central hub and peripherally located blades. This size constraint can place a limitation on the size and layout of the enclosure. Smaller game console enclosures are often attractive to users both from an aesthetic standpoint and also from a portability and storage standpoint. For example, smaller game consoles may be more easily stored in confined spaces such as a dormitory room. Similar small footprints are desired not only in game consoles but in other computing devices such as desktop computers, laptops, workstations, network attached storage devices, external (graphic) card enclosures amongst others.

The present invention is directed to overcoming or reducing the effects of one or more of the foregoing disadvantages.

### SUMMARY OF THE INVENTION

In accordance with one aspect of the present invention, a method of removing heat from a semiconductor chip in an enclosure of a computing device is provided. Heat is transferred from the semiconductor chip using a heat sink assembly that is thermally coupled to the semiconductor chip. Air is moved using an air mover positioned in the enclosure. The air mover is operable to move the air past a first portion of the heat sink assembly and recycle at least a portion of the air to pass a second portion of the heat sink assembly.

In accordance with another aspect of the present invention, a method of manufacturing is provided that includes placing a semiconductor chip in an enclosure of a computing device and thermally coupling a heat sink to the semiconductor chip. An air mover is placed in the enclosure. The air mover is operable to move air past the heat sink and recycle at least a portion of the air to again pass the heat sink.

In accordance with another aspect of the present invention, a computing device is provided that includes an enclosure, a semiconductor chip in the enclosure and a heat sink in thermal contact with the semiconductor chip. An air mover is in the enclosure and operable to move air past the heat sink and recycle at least a portion of the air to again pass the heat sink.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of a computing device that includes an enclosure;

FIG. 2 is a pictorial view of the exemplary embodiment of the computing device with the enclosure shown in phantom;

FIG. 3 is a sectional view of FIG. 2 taken at section 3-3;

FIG. 4 is a sectional view of a conventional game console;

FIG. 5 is an exploded pictorial view of an exemplary heat sink assembly and system board of an exemplary computing device;

FIG. 6 is a plot of change in device temperature versus air mover discharge rate for two exemplary semiconductor devices;

FIG. 7 is a plot of change in device temperature versus air mover discharge rate for two other exemplary semiconductor devices;

FIG. 8 is a pictorial view of an alternate exemplary embodiment of a reverse flow air mover; and

FIG. 9 is a sectional view like FIG. 3, but of an alternate exemplary embodiment of a computing device with an alternate exemplary heat sink assembly.

### DETAILED DESCRIPTION OF SPECIFIC EMBODIMENTS

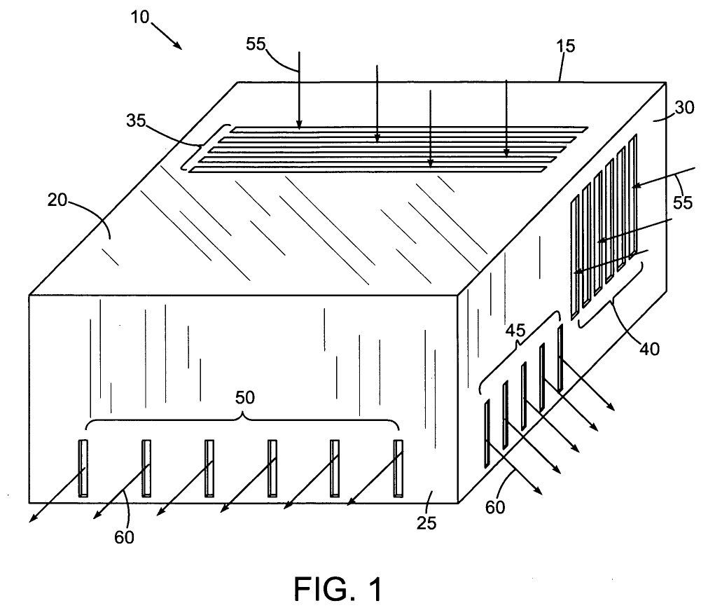

In the drawings described below, reference numerals are generally repeated where identical elements appear in more than one figure. Turning now to the drawings, and in particular to FIG. 1, therein is shown a pictorial view of an exemplary embodiment of a computing device 10 that includes an enclosure 15. The computing device 10 may be a computer, a game console, or other type of computing device. The enclosure 15 houses a variety of components that make up the computing device 10, but which are not visible in FIG. 1. The enclosure 15 may be a box-like structure that includes a plurality of sides, three of which are visible and labeled 20, 25 and 30. The side 20 may be provided with a group of air intake vents 35. The side 30 may be provided with another group of intake vents 40. The side 30 may be additionally provided with a group 45 of air outlet vents. Additionally, the side 25 may be provided with a group 50 of air outlet vents. The side of the enclosure 15 opposite to the side 30 and not visible in FIG. 1 may be provided with similar, albeit oppositely, positioned groups of intake and outlet vents. As will be described in more detail below, an air movement system within the enclosure 15 is configured so that intake air 55 may be drawn through the groups 35 and 40 of vents and subsequently discharged as outlet air 60 from the groups 45 and 50 of outlet vents. Of course, and as just noted, intake and outlet vents will be positioned on the non-visible side opposite to the side 30 as well. The enclosure 15 may be fabricated from a variety of materials such as well-known metals and plastics. The enclosure 15 may be a two or multi piece design such as a lid that fits on a case if desired.

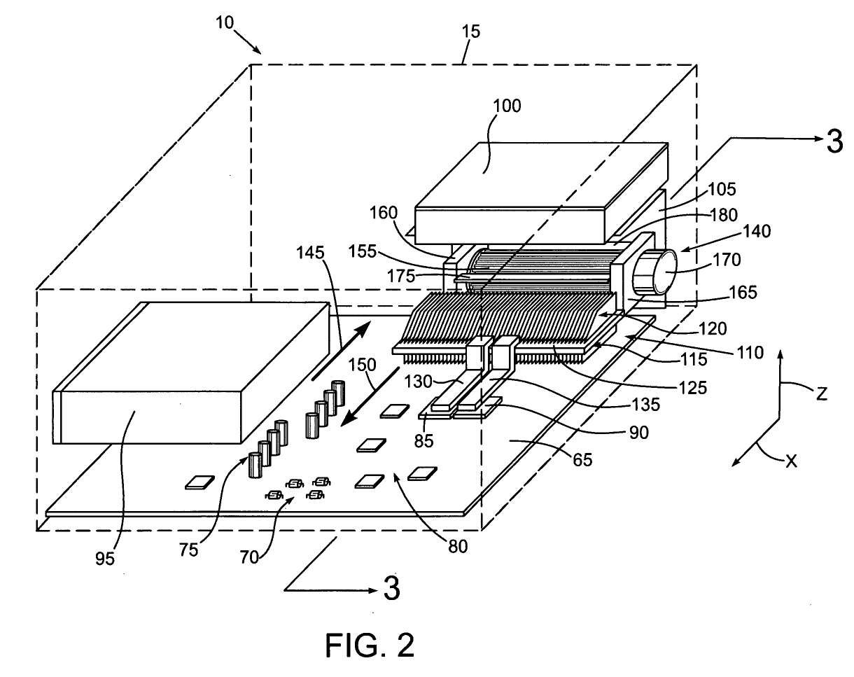

Additional details of the computing device 10 may be understood by referring now also to FIG. 2, which is a pictorial view of the computing device 10 and the enclosure 15 but with the enclosure 15 shown in phantom to reveal the various components housed inside. The computing device 10 includes a system board 65 that has a variety of electronic components. The board 65 itself may be constructed of well-known polymeric materials and consists of multiple layers of such materials interspersed with conductor traces (not visible) that link up the various components of the computing device 10. Typical examples of such components include resistors 70, capacitors 75, various integrated circuits 80 and two processors 85 and 90. It should be understood that the layout and population of various components of the system board 65 are subject to enormous variety. The integrated circuits 80 may include, for example, memory devices, chip set controllers, peripheral controllers, voltage regulators and other types of devices. The processors 85 and 90 may be graphics processors, microprocessors, or semiconductor chips that combine both graphics and general microprocessor capabilities. The computing device 10 may include one or more data storage/retrieval devices 95 and 100. For example, the storage retrieval device 95 may be an optical disk drive, such as a DVD or CD drive, and the data storage device 100 may be, for example, a solid state disk or hard disk drive. The storage device 95 will generally be supported by a structure or mount that is not visible in FIG. 2. The storage device 100 may be supported by any of a variety of different types of mounting schemes. In this illustrative embodiment, the drive 100 is seated on a L-shaped shelf 105.

A heat sink assembly 110 is provided to remove heat from the processors 85 and 90. The heat sink assembly 110 includes a first portion in the form of a lower heat fin array 115, a second portion in the form of an upper heat fin array 120 and a heat spreader plate 125 sandwiched between the upper and lower heat fin arrays 115 and 120. Heat spreaders 130 and 135 in the form of heat pipes, diamond bars, vapor chambers, graphite rods or like thermal members are in respective thermal contact with the processors 85 and 90. The spreader plate 125 may include an additional heat pipe that is in fluid communication with the heat spreaders 130 and 135 but is obscured by the upper heat fin array 120 in FIG. 2. Additional details of the spreader plate 125 will be shown in a subsequent figure and described accordingly. The heat fin arrays 115 and 120, the spreader plate 125 and the heat spreaders 130 and 135 are advantageously fabricated from thermally conductive materials, such as copper, nickel, aluminum, steel, combinations of these or the like. The heat spreaders 130 and 135 may be filled with a fluid, such as water, alcohol, glycol or the like.

An air mover 140 is positioned behind the heat sink assembly 110 and opposite the processors 85 and 90. The air mover 140 is advantageously designed to draw intake air represented by the arrow 145 past the upper heat fin array 120 and then return that air back past the lower heat fin array 115 as represented by the arrow 150. To accomplish this reversal in flow direction, the air mover 140 may be advantageously implemented as a crossflow blower that includes a cylindrical impeller 155. The impeller 155 is rotatably mounted between a pair of spaced-apart support plates 160 and 165. The impeller 155 is rotatable by way of an electric motor 170, which may be a DC or AC motor as desired. Incoming air is partially directed by way of a vortex tongue 170 that is mounted between the support plates 160 and 165. The vortex tongue 170 is configured much like an airfoil. Intake air is discharged in the direction of the arrow 150 by way of a guiding plate 180 that is partially obscured in FIG. 2, but will be shown in greater detail in a subsequent figure. A variety of reverse flow fans may be used. In an exemplary embodiment, a QG030 Series available from ebm-papst, Inc. may be selected. Ordinary air will be the most common fluid used for cooling. However, other gaseous ambients could be used, such as nitrogen, argon, carbon dioxide, etc., so it should be understood that the term “air” as used herein contemplates a gas or gas mixture.

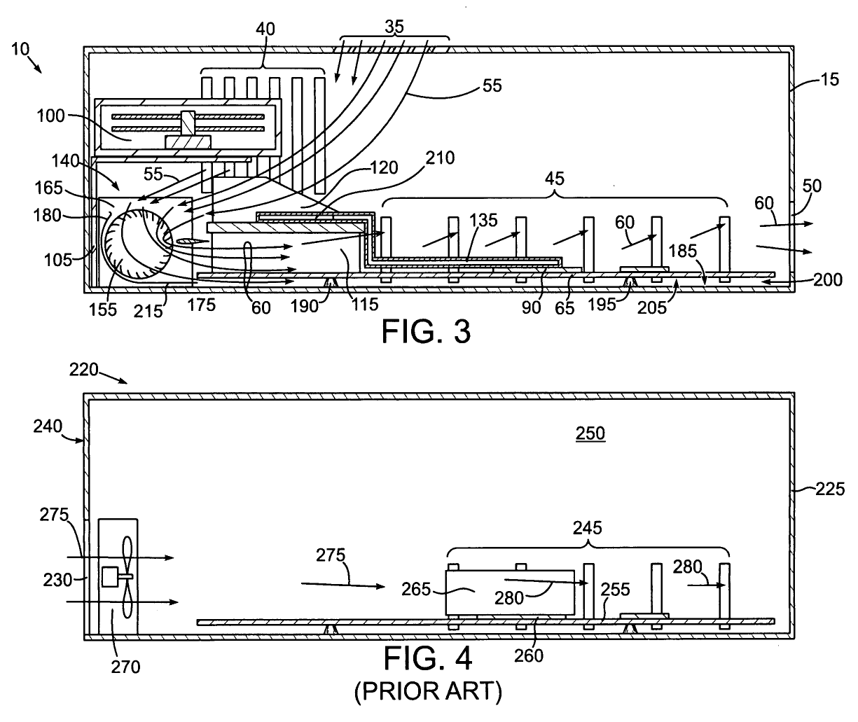

Additional detail of the air flow for the computing device 10 may be understood by referring now to FIG. 3, which is a sectional view of FIG. 2 taken at section 3-3. Before turning to a description of the air flow, a few of the features of the computing device 10 will be identified to provide context. Here, the groups 35, 40 and 45 of vents in the enclosure 15 that were shown in FIG. 1 are now shown as well. In addition, one member of the group 50 of vents is visible in FIG. 3. The position of section 3-3 is such that the processor 90 and the heat spreader 135 are shown in section, but the processor 85 shown in FIG. 2 is not visible. As noted briefly in conjunction with FIG. 2, the heat spreader 135 is in fluid communication with a heat pipe or spreader 210 that extends into and out of the page. The spreader plate 125 is in thermal contact with the heat spreaders 135 and 210 and also with the upper and lower heat fin arrays 115 and 120. The storage device 100 and its L-shaped supporting frame 105 are shown in section due to the location of section 3-3, the blade assembly 155 of the air mover 140, the vortex tongue 175 and the guiding plate 180 are shown in section but the support plate 165 is not. The system board 65 may be supported slightly above the lower surface 185 of the enclosure 15 by way of plural supports, two of which are shown and labeled 190 and 195. The supports 190 and 195 may be bolts, mounds, pillars or any of a variety of different types of structures used to support printed circuit boards. Note, however, that a small gap 200 is provided between the system board 65 and the lower surface 185 of the enclosure which provides a pathway for air to cool an underside 205 of the system board 65. This gap 200 is desirable where the underside 205 includes electronic components.

When the air mover 140 is activated, intake air 55 is drawn through the groups 35 and 40 of enclosure vents and pulled down past the upper heat fin array 120 and into the impeller 155. As the impeller 155 rotates (counterclockwise facing into the page), the intake air 55 is deflected back toward the lower fin array 115 by way of the curved guiding plate 180. Return air 60 is prevented from being thrust upward substantially by the vortex tongue 175. Thus, the vortex tongue 175 and the bottom portion 215 of the guiding plate 180 serve essentially as a rectangular shaped discharge chute through which return air 60 is routed past the lower heat fin array 115. The return air 60 then proceeds from left to right in the page and exits either the group of vents 45 or the group of vents 50 of the enclosure 15.

The use of a reverse air flow path provides for enhanced cooling efficiency. For example, intake air 55 enters the group 35 of vents at some ambient temperature to. Depending on the average temperature of the interior of the enclosure 15, the intake air 55 will be heated to some temperature t₁ prior to passing the upper heat fin array 120 where t₁>t₀. As the intake air 55 passes the upper heat fin array 120 and cycles through the air mover 140, heat is transferred from both the spreader plate 125 and fin array 120 and the air temperature increases to some higher temperature t₂ where t₂>t₁. At this point, the discharge air 60 at temperature t₂ is still cooler than the spreader plate 125, the lower heat fin array 115, the system board 65 and the processor 90, particularly if the computing system 10 has been active for some time and reached typical operating conditions. Thus, the discharge air 60 at temperature t₂ is still capable of convectively transferring heat from those heat dissipation devices and electronic components as it transits toward and out the groups 45 and 50 of vents.

The skilled artisan will also appreciate that the exemplary crossflow air mover 140 has a relatively small vertical footprint along a vertical or Z-axis and an attendant small footprint along a horizontal or X-axis. Beneficial air flow may be obtained without unduly constraining enclosure size or geometry.

It may be useful at this point to contrast the cooling system for the computing device 10 with a cooling system for a conventional but similar computing device. In this regard, attention is now turned to FIG. 4, which is a sectional view of a conventional game console 220. The game console 220 includes an enclosure 225 with a group 230 of intake vents located at the back 240, and a group 245 of outlet vents located along a side 250 of the enclosure 225. Another group of discharge vents is located in the side of the enclosure 225 that is opposite to the side 240 but not visible in this sectional view. In this illustration, a system board 255 includes at least one electronic component 260 that requires active cooling. A heat sink 265 is positioned on the system board 255. A conventional axial fan 270 is positioned proximate the inlet vents 230. Intake air 275 is drawn in through the inlet vents 230 and moved in a generally left to right as viewed in the page by the axial fan 270 and discharged out of the group 245 of discharge vents. The flow is generally unidirectional in that the air makes a single pass through the enclosure 225 before discharging out of the group 245 of vents. In this way, although power is expended to move the air 275, only a single pass is used. Thus the discharge air 280 leaves the enclosure 225 while still possessing some unused cooling capacity. Furthermore, the acoustic output of the conventional arrangement will generally be higher than the exemplary embodiments disclosed herein. This is due to the close proximity of the conventional axial fan 270 to the inlet vents 230. Noise due to fan operation and air movement past the vents 230 is readily transmitted to the surroundings. In contrast, the exemplary embodiments disclosed herein place the air movers 140 and 330 (see FIGS. 2, 3 and 8) further from vents.

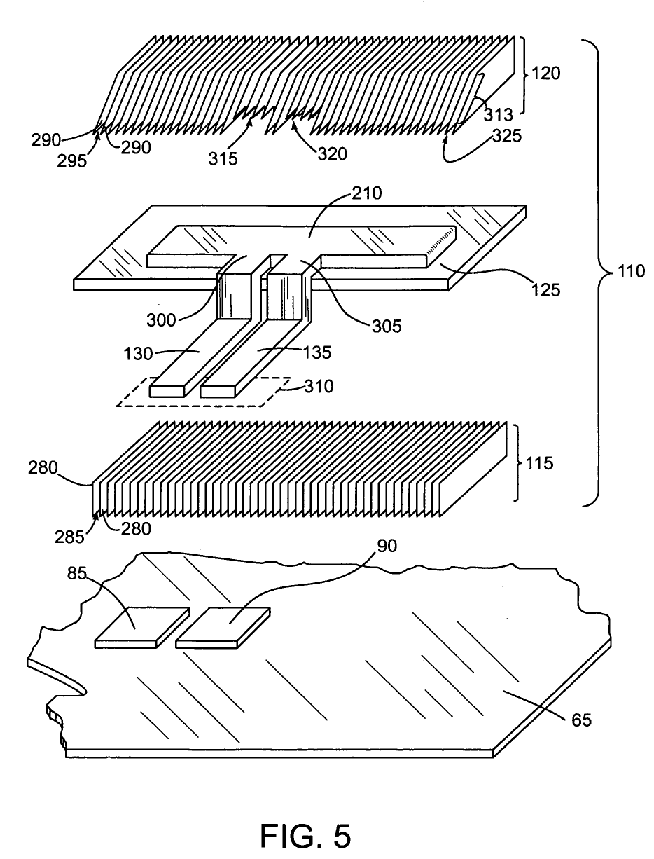

Additional details of the heat sink assembly 110 may be understood by referring now to FIG. 5, which is an exploded pictorial of the heat sink assembly 110 and a portion of the system board 65 that includes the processors 85 and 90. As noted elsewhere herein, the lower heat fin array 115 and the upper heat fin array 120 bracket the spreader plate 125. The lower heat fin array 115 includes multiple fins 280 spaced apart by gaps 285 that enable air flow between adjacent fins 280. Optionally, other heat sink configurations, such as honeycomb, porous materials functioning as fins, or other designs may be used. The upper heat fin array 120 similarly includes multiple fins 290 spaced apart by gaps 295 that enable air flow between adjacent fins 290. The heat spreaders 130 and 135 include respective elbow portions 300 and 305 that connect to the heat spreader 210. Although the heat spreaders 130 and 135 may be seated directly on the processors 85 and 90, respectively, an optional spreader plate shown in phantom and labeled 310 may be connected to the heat spreaders 130 and 135 and used to make thermal contact with the processors 85 and 90 if desired. The upper heat fin array 120 includes a slanted front portion 313 that is designed to provide a slightly lower drag for intake air to pass there through. In order to accommodate the elbow portions 300 and 305 of the heat spreaders 130 and 135, cut outs 315 and 320 may be provided in the upper heat fin array 120 that are sized appropriately to accommodate the sizes of the elbow portions 300 and 305. A similar cut out portion that is not visible but formed in the under surface underside 325 of the upper fin array 120 may be provided in order to accommodate the heat spreader 210 that extends across the upper surface of the spreader plate 125. Obviously such cut outs 315 and 320 will not be necessary in the event that the spreader plate 125 and the heat spreaders 130, 135 and 210 present a more conformal upper surface. The exact configurations of the upper and lower fin arrays 115 and 120 are subject to huge variety as is the case with heat fin arrays in general.

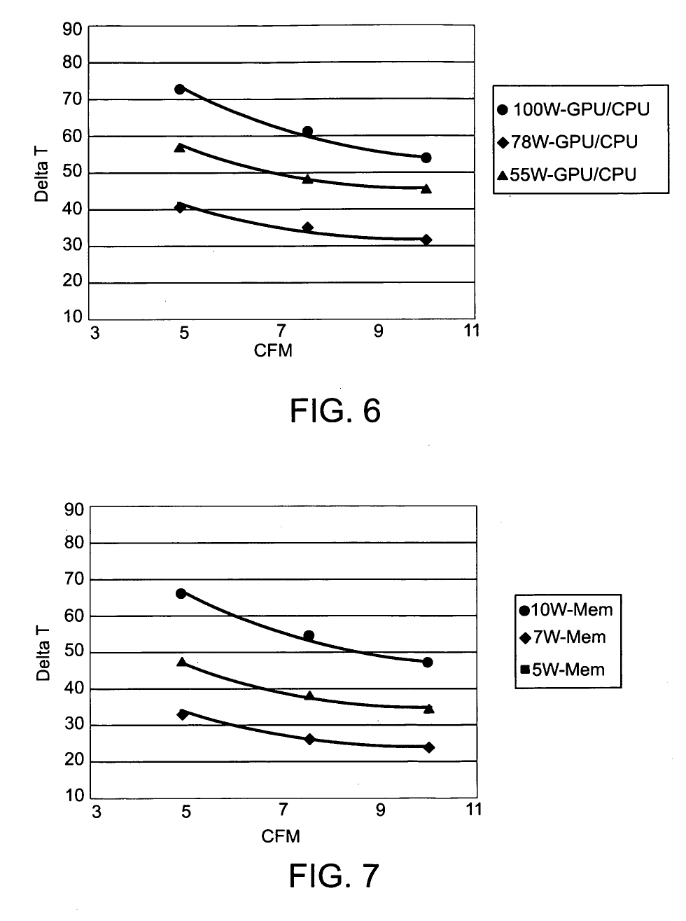

Computer modeling was performed to examine the relationship between air mover discharge rate and temperature rise for the exemplary crossflow air mover 140 depicted in FIGS. 2 and 3 and four different integrated circuits: a 100 watt processor (graphics processing unit (GPU) or central processing unit (CPU)), a 78 watt GPU/CPU, a 55 watt GPU/CPU, a 10 watt memory device, a 7 watt memory device and a 5 watt memory device. The data is set forth in the following tables and plotted in FIGS. 6 and 7, respectively.

TABLE 1

| | | | | | Temp. of |
|---|---|---|---|---|---|
| | | % of | | | Integrated |
| | | Maximum Air | | Integrated | Circuit above |
| | Air mover | mover | | Circuit | ambient |
| Integrated | Discharge | Discharge | Ambient Temp. | Temp. | (Delta T in |
| Circuit | Rate (ft³/min.) | Capacity | (C.°) | (C.°) | C.°) |
| 100 W | 5 | 60 | 25 | 98 | 73 |
| GPU/CPU | 7.5 | 75 | 25 | 86 | 61 |
| | 10 | 90 | 25 | 81 | 56 |
| 78 W | 5 | 60 | 25 | 82 | 57 |
| GPU/CPU | 7.5 | 75 | 25 | 73 | 48 |
| | 10 | 90 | 25 | 69 | 44 |
| 55 W | 5 | 60 | 25 | 65 | 40 |
| GPU/CPU | 7.5 | 75 | 25 | 59 | 34 |
| | 10 | 90 | 25 | 56 | 31 |

TABLE 2

| | | | | | Temp. of |
|---|---|---|---|---|---|
| | | % of | | | Integrated |
| | | Maximum Air | | Integrated | Circuit above |
| | Air mover | mover | Ambient | Circuit | ambient |
| Integrated | Discharge | Discharge | Temp. | Temp. | (Delta T in |
| Circuit | Rate (ft³/min.) | Capacity | (C.°) | (C.°) | C.°) |
| 10 W Memory | 5 | 60 | 25 | 92 | 67 |
| | 7.5 | 75 | 25 | 79 | 54 |
| | 10 | 90 | 25 | 73 | 48 |
| 7 W Memory | 5 | 60 | 25 | 72 | 47 |
| | 7.5 | 75 | 25 | 63 | 38 |
| | 10 | 90 | 25 | 59 | 34 |
| 5 W Memory | 5 | 60 | 25 | 58 | 33 |
| | 7.5 | 75 | 25 | 52 | 27 |
| | 10 | 90 | 25 | 49 | 24 |

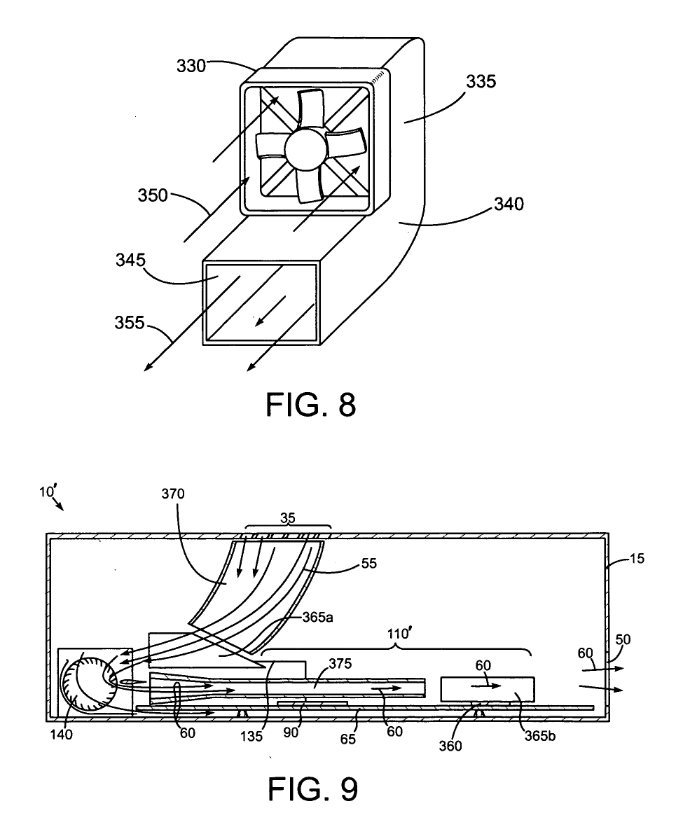

In an alternate exemplary embodiment, an axial air mover can be matched with a reverse duct to achieve a crossflow with an axial air mover. A pictorial view of such an exemplary arrangement is shown in FIG. 8. An axial air mover 330 is connected to a duct 335 with a reverse elbow 340 and an outlet 345. Intake air 350 is routed through the duct 335 and discharged as outlet air 355 in reverse direction from the outlet 345. This solution may take up more space than a comparable capacity crossflow air mover, but may still prove attractive where the available space inside a computing device enclosure is at a lower premium.

Another exemplary embodiment may be understood by referring now to FIG. 9, which is a sectional view like FIG. 3. In this illustrative embodiment, a computing device 10′ is depicted schematically and in section. In many respects, the computing device 10′ may be configured like the computing device 10 embodiment described elsewhere herein. Thus, an enclosure 15 houses a system board 65 fitted with a semiconductor chip 90. Another semiconductor chip 360 is also coupled to the system board 65. Vents 35 and 50 may be provided for and a crossflow air mover 140 may be mounted in the enclosure 15. Here a heat sink assembly 110′ includes a first portion 365a in the form of a heat sink and a second portion 365b in the form of another heat sink. The heat sink assembly 110′ is in thermal communication with the semiconductor chip 90. This may be accomplished by thermally coupling the portion 365a, the portion 365b or both to the semiconductor chip 90. Optionally, the portion 365b may be thermally coupled to the semiconductor chip 360 or some other device if desired. The portion 365a may be thermally coupled to the semiconductor chip 90 by way of the heat spreader 135 represented schematically by the black line. The portions 365a and 365b of the heat sink assembly 110′ may be heat fin arrays or other types of heat sinks. An inlet duct 370 may provided to route inlet air 55 drawn by the air mover 140 past the portion 365a. Discharge air 60 may be crossflow so that at least a portion thereof is moved past the portion 365b in different direction than the inlet air 55. An outlet duct 375 may be provided to spatially direct at least some of the discharge air 60 past the portion 365b.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of removing heat from a semiconductor chip in an enclosure of a computing device, comprising:
transferring heat from the semiconductor chip using a heat sink assembly thermally coupled to the semiconductor chip; and
moving air using an air mover positioned in the enclosure, the air mover operable to move the air past a first portion of the heat sink assembly and recycle at least a portion of the air to pass a second portion of the heat sink assembly.

2. The method of claim 1, wherein the air mover is operable to move the air in a first direction past the first portion of the heat sink assembly and recycle the at least a portion of the air in a second direction opposite to the first direction.

3. The method of claim 1, wherein the air mover comprises a crossflow fan.

4. The method of claim 1, wherein the air mover comprises an axial fan in fluid communication with a duct having a reversing flow path.

5. The method of claim 1, wherein the computing device comprises a game console.

6. The method of claim 1, wherein the semiconductor chip comprises a graphics processor.

7. The method of claim 1, comprising a heat spreader to thermally couple the semiconductor chip to the heat sink assembly.

8. The method of claim 7, wherein the heat spreader comprises a heat pipe.

9. The method of claim 1, wherein the first portion of the heat sink assembly comprises a first portion of a heat sink and the second portion of the heat assembly comprises a second portion of the heat sink.

10. The method of claim 9, wherein the first portion of the heat sink comprises a first heat fin array, the second portion of the heat sink comprises a second heat fin array and the heat sink comprises a spreader plate coupled between the first and second heat fin arrays.

11. A method of manufacturing, comprising:
placing a semiconductor chip in an enclosure of a computing device;
thermally coupling a heat sink to the semiconductor chip; and
placing an air mover in the enclosure, the air mover being operable to move air past the heat sink and recycle at least a portion of the air to again pass the heat sink.

12. The method of claim 10, wherein the air mover is operable to move the air in a first direction past the heat sink and recycle the at least a portion of the air in a second direction opposite to the first direction.

13. The method of claim 10, wherein the air mover comprises a crossflow fan.

14. The method of claim 10, wherein the air mover comprises an axial fan in fluid communication with a duct having a reversing flow path.

15. The method of claim 10, wherein the computing device comprises a game console.

16. The method of claim 10, wherein the semiconductor chip comprises a graphics processor.

17. The method of claim 10, comprising using a heat pipe to thermally couple the semiconductor chip to the heat sink.

18. The method of claim 10, wherein the heat sink comprises a first heat fin array, a second heat fin array and a spreader plate coupled between the first and second heat fin arrays.

19. A computing device, comprising:
an enclosure;
a semiconductor chip in the enclosure;
a heat sink in thermal contact with the semiconductor chip; and
an air mover in the enclosure and operable to move air past the heat sink and recycle at least a portion of the air to again pass the heat sink.

20. The computing device of claim 18, wherein the air mover is operable to move the air in a first direction past the heat sink and recycle the at least a portion of the air in a second direction opposite to the first direction.

21. The computing device of claim 18, wherein the air mover comprises a crossflow fan.

22. The computing device of claim 18, wherein the air mover comprises an axial fan in fluid communication with a duct having a reversing flow path.

23. The computing device of claim 18, wherein the computing device comprises a game console.

24. The computing device of claim 18, wherein the semiconductor chip comprises a graphics processor.

25. The computing device of claim 18, comprising a heat pipe thermally coupling the semiconductor chip to the heat sink.

26. The computing device of claim 18, wherein the heat sink comprises a first heat fin array, a second heat fin array and a spreader plate coupled between the first and second heat fin arrays.
